(19) United States
(12) Patent Application Publication
(10) Pub. No.: US 2024/0183732 A1
(43) Pub. Date: Jun. 6, 2024

(54) MEMS SENSOR AND MANUFACTURING METHOD THEREOF

(71) Applicant: ROHM CO., LTD., Kyoto (JP)

(72) Inventor: Masahiro SAKURAGI, Kyoto (JP)

(73) Assignee: ROHM CO., LTD., Kyoto (JP)

(21) Appl. No.: 18/525,773

(22) Filed: Nov. 30, 2023

(30) Foreign Application Priority Data
Dec. 5, 2022 (JP) 2022-194457

(51) Int. Cl. G01L 9/00

(52) U.S. Cl. CPC G01L 9/0072

(57) ABSTRACT

The present disclosure provides a MEMS sensor. The MEMS sensor includes: a semiconductor substrate having a first surface and a second surface opposite to the first surface, and including a cavity; a membrane on the first surface to seal the cavity; a first region of a first conductivity type formed at a bottom of the cavity; and a second region of a second conductivity type formed on the membrane, facing the first region and separated from the first region by the cavity.

### TECHNICAL FIELD

The present disclosure relates to a micro-electro-mechanical system (MEMS) sensor and a method of manufacturing a MEMS sensor.

### BACKGROUND

Patent publication 1 discloses a MEMS sensor having a cavity and a movable portion closing the cavity. Based on the movement of the movable portion produced by a change in a pressure inside the cavity, a pressure produced on the MEMS sensor is detected.

### PRIOR ART DOCUMENT

### Patent Publication

[Patent document 1] Japan Patent Publication No. 2021-025966

### BRIEF DESCRIPTION OF THE DRAWINGS

FIG. 1 is a schematic plan view of a MEMS sensor according to a first embodiment of the present disclosure.

FIG. 2 is a schematic section diagram of the MEMS sensor according to the first embodiment of the present disclosure and is a cross section along II-II of FIG. 1.

FIG. 3A is a diagram of a part of a manufacturing process of the MEMS sensor according to the first embodiment of the present disclosure.

FIG. 3B is a diagram of a next process of that in FIG. 3A.

FIG. 3C is a diagram of a next process of that in FIG. 3B.

FIG. 3D is a diagram of a next process of that in FIG. 3C.

FIG. 3E is a diagram of a next process of that in FIG. 3D.

FIG. 3F is a diagram of a next process of that in FIG. 3E.

FIG. 3G is a diagram of a next process of that in FIG. 3F.

FIG. 3H is a diagram of a next process of that in FIG. 3G.

FIG. 4 is a schematic section diagram of a MEMS sensor according to a second embodiment of the present disclosure.

FIG. 5A is a diagram of a part of a manufacturing process of the MEMS sensor according to the second embodiment of the present disclosure.

FIG. 5B is a diagram of a next process of that in FIG. 5A.

FIG. 5C is a diagram of a next process of that in FIG. 5B.

FIG. 5D is a diagram of a next process of that in FIG. 5C.

FIG. 5E is a diagram of a next process of that in FIG. 5D.

FIG. 5F is a diagram of a next process of that in FIG. 5E.

FIG. 5G is a diagram of a next process of that in FIG. 5F.

FIG. 5H is a diagram of a next process of that in FIG. 5G.

FIG. 5I is a diagram of a next process of that in FIG. 5H.

FIG. 5J is a diagram of a next process of that in FIG. 5I.

FIG. 6 is a schematic section diagram of a MEMS sensor according to a third embodiment of the present disclosure.

FIG. 7 is a sectional diagram illustrating a variation example of the present disclosure.

### DETAILED DESCRIPTION OF THE EMBODIMENTS

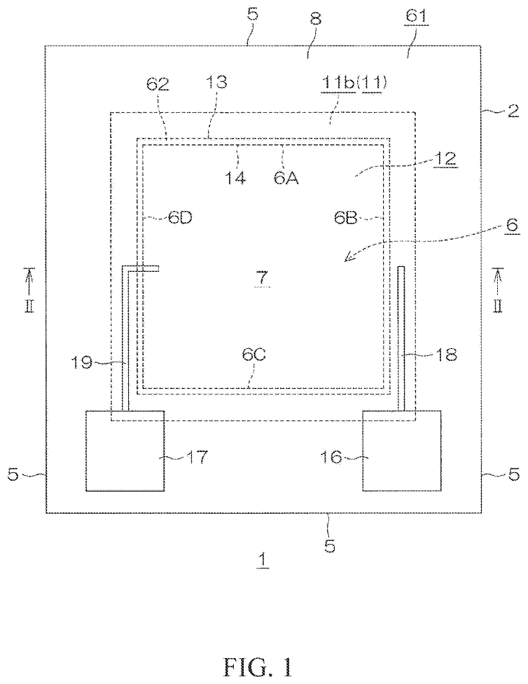

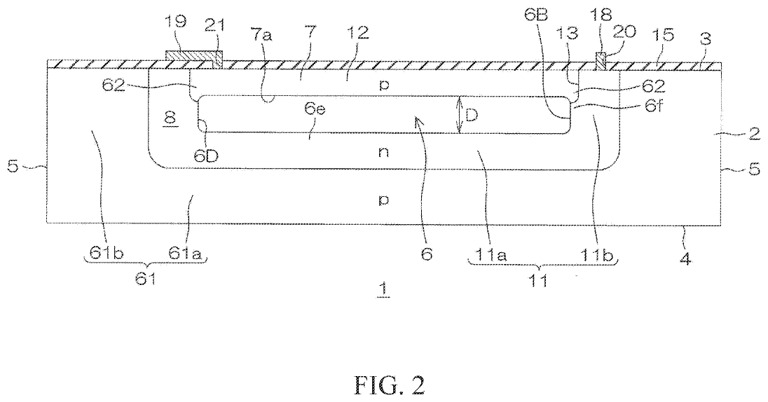

FIG. 1 shows a schematic plan view of a MEMS sensor 1 according to a first embodiment of the present disclosure. FIG. 2 shows a schematic section diagram of the MEMS sensor 1 according to the first embodiment of the present disclosure and is a cross section along II-II of FIG. 1.

The MEMS sensor 1 is, for example, an electrostatic capacitive sensor. The MEMS sensor 1 can be applied to various sensors such as air pressure sensors and pressure sensors. The MEMS sensor 1 includes a semiconductor substrate 2. In this embodiment, the semiconductor substrate 2 is a p-type (second conductivity type) semiconductor substrate 2. In this embodiment, the semiconductor substrate 2 is a silicon substrate. The semiconductor substrate 2 has a first surface 3 and a second surface 4 opposite to the first surface 3. The first surface 3 and the second surface 4 of the semiconductor substrate 2 can also be respectively referred to as a front surface and a back surface of the semiconductor substrate 2. Moreover, the semiconductor substrate 2 has an end surface 5. In this embodiment, the semiconductor substrate 2 is quadrilateral in shape in a plan view. The end surface 5 includes four end surfaces 5 formed on four sides of the semiconductor substrate 2 in the plan view. The end surface 5 of the semiconductor substrate 2 can also be referred to as a side surface of the semiconductor substrate 2, or can be referred to as a third surface. Moreover, a thickness of the semiconductor substrate 2 is, for example, 100 μm or more and 775 μm or less.

The semiconductor substrate 2 has a cavity 6, a membrane 7 formed on the first surface 3, and a fixing portion 8. The cavity 6 is a cavity formed on an inside of the semiconductor substrate 2. The membrane 7 is, for example, film-like, and is disposed at an opening of the cavity 6 to seal the cavity 6. The fixing portion 8 is a part supporting the membrane 7. In this embodiment, a part other than the cavity 6 and the film 7 in the semiconductor substrate 2 is the fixing portion 8.

As shown in FIG. 1, the cavity 6 is formed to be substantially quadrilateral in shape in the plan view. In the plan view, the cavity 6 has a first side 6A, a second side 6B, a third side 6C and a fourth side 6D. A depth D of the cavity 6 is, for example, 0.5 μm or more and 20 μm or less. The depth D of the cavity 6 can also be a distance from an opposite surface 7a of the membrane 7 to a bottom 6e of the cavity 6.

The membrane 7 has a fixed thickness. The thickness of the membrane 7 is, for example, 1 μm or more and 30 μm or less. Preferably, the thickness of the membrane 7 is, for example, 7 μm. The membrane 7 has the opposite surface 7a facing the bottom 6e of the cavity 6. The membrane 7 is deformable relative to the cavity 6. An interface line between the membrane 7 and the fixing portion 8 is substantially quadrilateral in shape in the plan view, and is aligned with the four sides 6A to 6D of the cavity 6 in the plan view. The cavity 6 is sealed by the membrane 7, and thus an inside of the cavity 6 is kept vacuum. The membrane 7 is deformed in a thickness direction of the semiconductor substrate 2 relative to a change in a difference of atmospheric pressure around the vacuum environment.

The semiconductor substrate 2 includes an n-type (first conductivity type) first region 11, a p-type (second conductivity type) second region 12, and a p-type third region 61. The second region 12 faces the first region 11 in the thickness direction of the semiconductor substrate 2, and is separated from the first region 11 by the cavity 6. The third region 61 is formed by a p-type region other than the first region 11 and the second region 12 in the semiconductor substrate 2. In this embodiment, the p-type third region 61 is formed over an entirety of the semiconductor substrate 2 from the first surface 3 to the second surface 4 in the thickness direction. The first region 11 is selectively formed on a surface layer portion of the third region 61 to surround the cavity 6, and thus the second region 12 is selectively formed on a surface layer portion of the first region 11 in a region further inside than the first region 11.

The first region 11 includes a first portion 11a forming the bottom 6e of the cavity 6, and a second portion 11b forming a side 6f of the cavity 6. The first portion 11a is formed as quadrilateral in shape in the plan view, and the second portion 11b is formed around an entirety of a peripheral portion of the first portion 11a and formed as a loop in the plan view. The second portion 11b extends from the peripheral portion of the first portion 11a to the first surface 3. A lower surface (an end surface on a side of the second surface 4) of the first portion 11a and a lower surface (an end surface on a side of the second surface 4) of the second portion 11b are a same surface along a horizontal direction of the second surface 4. The first portion 11a and the second portion 11b are both formed by an n-type diffusion layer. An n-type impurity concentration of the first portion 11a and the second portion 11b can be between about 1.0×10¹⁵ cm⁻³ and about 1.0×10¹⁹ cm⁻³.

The second region 12 is a surface which is formed from the opposite surface 7a to the first surface 3 in the thickness direction of the membrane 7 and exposed through the opposite surface 7a and the first surface 3. The second region 12 extends over an entirety of the membrane 7 from a center of the membrane 7 to a periphery of the membrane 7 (an interface 14 between the membrane 7 and the fixing portion 8) along a horizontal direction of the first surface 3. A periphery of the second region 12 is surrounded by the second portion 11b of the first region 11. In other words, the second portion 11b of the first region 11 surrounds the periphery of the second region 12. An outer periphery of the second region 12 is connected with the second portion 11b. As shown in FIG. 1, an interface 13 between the second region 12 and the second portion 11b is closer to the outside (the side of the four end surfaces 5) than the interface 14 (that is, an outer periphery of the cavity 6) between the membrane 7 and the fixing portion 8.

Accordingly, the second region 12 has a pull-out portion 62 pulled further outside in the horizontal direction than the four sides 6A to 6D of the cavity 6. The pull-out portion 62 is formed as a loop along a full periphery of the four sides 6A to 6D, as shown in FIG. 1. A portion of the pull-out portion 62 protrudes closer to the bottom 6e of the cavity 6 along the side 6f of the cavity 6 than the opposite surface 7a, and forms an upper end of the side 6f of the cavity 6.

The second region 12 is formed by a p-type diffusion layer. The second region 12 is formed globally over the membrane 7. A p-type impurity concentration of the second region 12 can be between about 1.0×10¹⁵ cm⁻³ and about 1.0×10²¹ cm⁻³.

The third region 61 includes a first portion 61a formed on the second surface 4 of the semiconductor substrate 2, and a second portion 61b formed on the end surface 5 of the semiconductor substrate 2. The first portion 61a is formed as quadrilateral in shape in the plan view, and the second portion 61b is formed as a loop around the entirety of the peripheral portion of the first portion 61a in the plan view and surrounds the first region 11. The second portion 61b extends from the second surface 4 to the first surface 3. A lower surface of the first portion 61a and a lower surface of the second portion 61b are formed as a same surface, and form the second surface 4.

Referring to FIG. 2, an insulation layer 15 is formed on the first surface 3 of the semiconductor substrate 2. The insulation layer 15 can include, for example, silicon oxide (SiO₂) or silicon nitride (SiN). The insulation layer 15 covers the membrane 7 and the fixing portion 8. More specifically, the insulation layer 15 integrally covers an entirety of the first surface 3.

Referring to FIG. 1, the MEMS sensor 1 further includes metal terminals 16 and 17, and contacts 18 and 19. The metal terminals 16 and 17 include a first metal terminal 16 and a second metal terminal 17. The metal terminals 16 and 17 are formed on the insulation layer 15. In the plan view, the metal terminals 16 and 17 are arranged to be separated along the end surface 5 of the semiconductor substrate 2. The contacts 18 and 19 include a first contact 18 and a second contact 19. One end of the first contact 18 is connected to the second portion 11b of the first region 11 on the first surface 3 through a contact hole 20 (referring to FIG. 2) formed at the insulation layer 15. The other end of the first contact 18 is connected to the first metal terminal 16. One end of the second contact 19 is connected to the second region 12 on the first surface 3 through a contact hole 21 (referring to FIG. 2) formed at the insulation layer 15. The other end of the second contact 19 is connected to the second metal terminal 17.

Moreover, although not shown, a passivation film can also be formed on the insulation layer 15 to cover the first and second metal terminals 16 and 17 and the first and second contacts 18 and 19.

As described above, the MEMS sensor 1 is an electrostatic capacitive sensor. When a bias voltage is applied to the first and second metal terminals 16 and 17, the bias voltage is applied to the first contact 18 and the second contact 19. Accordingly, a potential difference between the first portion 11a of the first region 11 and the second region 12 becomes constant, and the first region 11 and the second region 12 having different conductivity types from each other function as electrode portions.

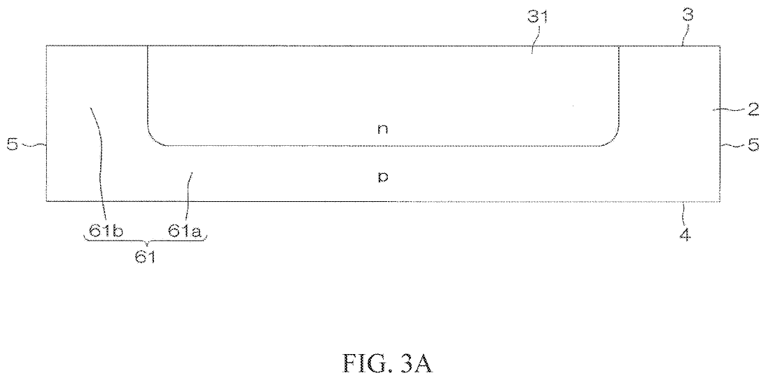

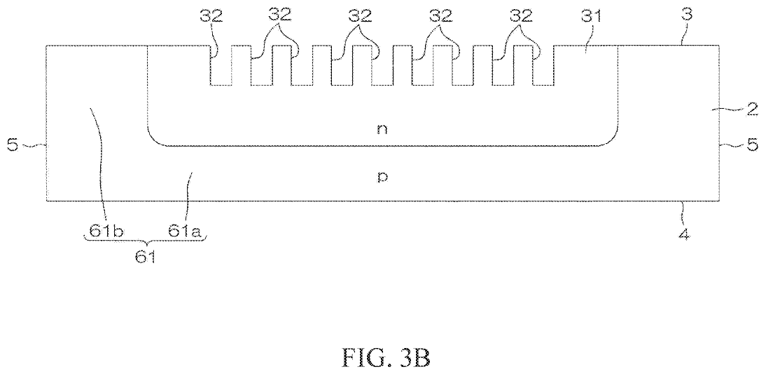

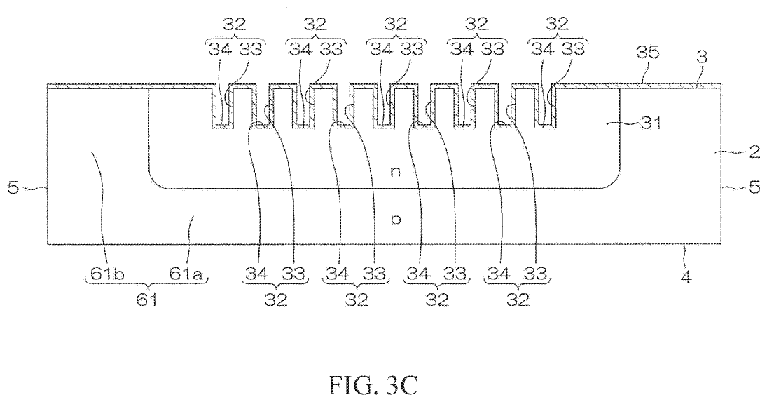

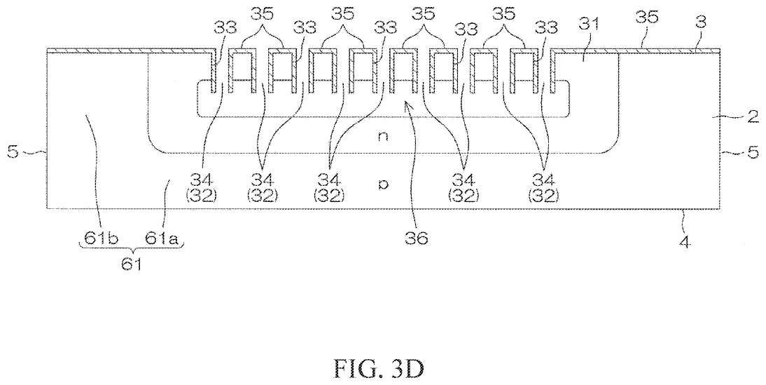

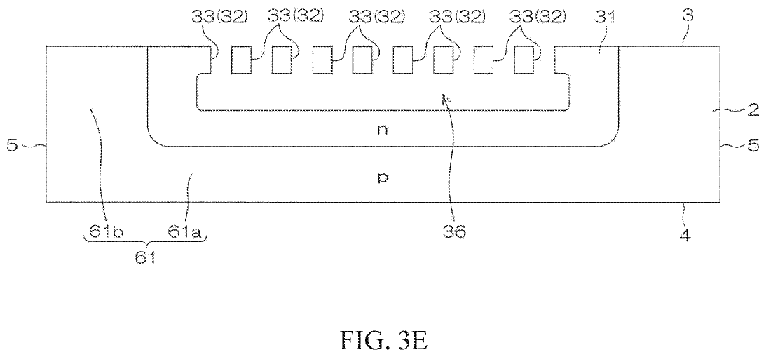

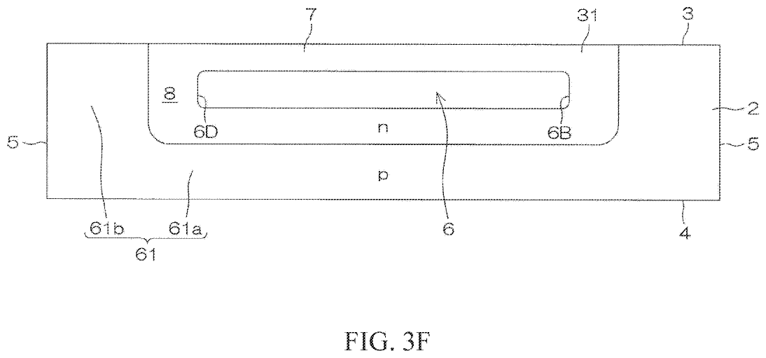

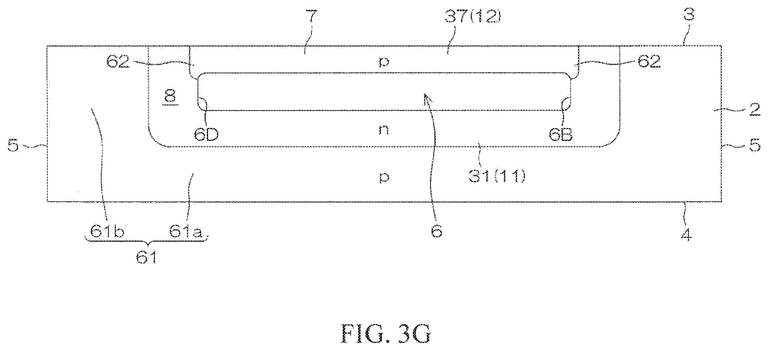

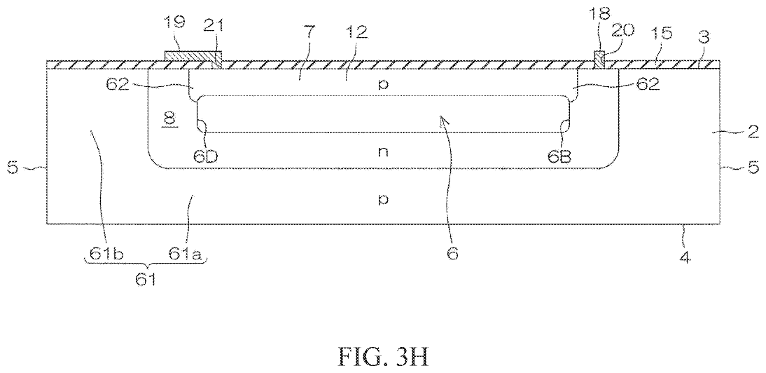

FIG. 3A to FIG. 3H show diagrams of a part of a manufacturing process of the MEMS sensor 1 according to the first embodiment of the present disclosure.

To manufacture the MEMS sensor 1, for example, as shown in FIG. 3A, a semiconductor substrate 2 including a silicon substrate is prepared. The semiconductor substrate 2 is p-type semiconductor wafer.

An n-type impurity is selectively introduced into the first surface 3 of the semiconductor substrate 2. Accordingly, an n-type first diffusion layer 31 is formed on the first surface 3 of the semiconductor substrate 2 (forming of a first diffusion layer).

Next, multiple holes 32 recessed from the first surface 3 are formed in the first diffusion layer 31 (forming of holes), as shown in FIG. 3B. The forming of the multiple holes 32 is implemented by, for example, deep dig etching (Bosch method). In the Bosch method, an area of a cross section perpendicular to a depth direction of the multiple holes 32 formed is constant.

Next, as shown in FIG. 3, by means of chemical vapor deposition (CVD), a protection film 35 is formed on the first surface 3, sidewalls 33 of the multiple holes 32, and bottom walls 34 of the multiple holes 32 (forming of a protective film). Accordingly, the first surface 3, the sidewalls 33 of the multiple holes 32 and the bottom walls 34 of the multiple holes 32 are covered by the protective film 35. The protective film 35 is, for example, silicon oxide.

Next, the protective film 35 is removed from the bottom walls 34 of the multiple holes 32 (removing of the protective film). Accordingly, a state of exposing the bottom walls 34 through the protective film 35 is formed on an inside of the multiple holes 32.

Next, as shown in FIG. 3D, the first diffusion layer 31 is isotropically etched. The etching is performed by an etching gas acting on the semiconductor material around the bottom walls 34 of the multiple holes 32 through the multiple holes 32 (etching). Accordingly, a connecting cavity 36 is formed below the multiple holes 32 (forming of a connecting cavity).

Next, as shown in FIG. 3E, the protective film 35 is entirely removed by means of etching. That is to say, the protective film 35 is removed from the sidewalls 33 of the multiple holes 32 (removing of a second protective film). The etching can be, for example, etching that selectively removes silicon oxide.

Next, as shown in FIG. 3F, the multiple holes 32 are closed (closing of holes). More specifically, by means of thermal migration, the multiple holes 32 are closed by partially moving the semiconductor material, that is, Si, of the first diffusion layer 31 around the multiple holes 32. Accordingly, a cavity 6 surrounded by the first diffusion layer 31 is formed, and thereby a membrane 7 sealing the cavity 6 is formed (forming of a cavity). The membrane 7 is merely a portion formed by Si, and is configured to form integrally with the fixing portion 8 that similarly includes Si without any connecting portion.

By implementing isotropic etching before thermal processing (thermal migration), the depth D (referring to FIG. 2) of the formed cavity 6 can become a desired depth and the thickness of the membrane 7 can become a desired thickness.

Moreover, processes shown in FIG. 3C to FIG. 3E can be omitted, and thermal migration is performed on the multiple holes 32 formed by the forming of holes in FIG. 3B. More specifically, by means of heat migration, the plurality of holes 32 are closed by partially moving the semiconductor material, that is, Si, of the first diffusion layer 31 around the multiple holes 32, and the cavity 6 surrounded by the first diffusion layer 31 is formed (forming of a cavity).

Next, as shown in FIG. 3G, a p-type impurity is selectively introduced into the membrane 7. Accordingly, a p-type second diffusion layer 37 is formed on the membrane 7 in a way opposite to the first diffusion layer 31 at the bottom 6e of the cavity 6 (forming of a second diffusion layer). The second diffusion layer 37 becomes the second region 12. A remaining region not introduced with the p-type impurity in the first diffusion layer 31 becomes the first region 11.

Next, as shown in FIG. 3H, the insulation layer 15 is formed on the first surface 3 of the semiconductor substrate 2 by means of, for example, CVD. Next, the metal terminals 16 and 17 and the contacts 18 and 19 are formed on the insulation layer 15 by means of, for example, sputtering and patterning. Then, the MEMS sensor 1 can be obtained by cutting the semiconductor substrate 2 into individual chip sizes.

Referring to FIG. 0.1 and FIG. 2, in the MEMS sensor 1, the p-type second region 12 formed on the membrane 7 faces the first portion 11a of the n-type first region 11 formed at the bottom 6e of the cavity 6 and is separated from the first portion 11a by the cavity 6. When the membrane 7 receives a pressure from the first surface 3, the membrane 7 is deformed in a thickness direction of the semiconductor substrate 2 due to a pressure difference produced between an inside and an outside of the cavity 6. A distance between the first portion 11a and the second region 12 changes as the membrane 7 is deformed, and an electrostatic capacitance between the first portion 11a and the second region 12 also changes. For example, when a bias voltage is applied to the first contact 18 and the second contact 19, a potential difference between the first portion 11a of the first region 11 and the second region 12 becomes constant, and the first region 11 and the second region 12 of different conductivity types from each other function as electrode portions. A pressure generated on the MEMS sensor 1 can be detected based on the change in the electrostatic capacitance between the first region 11 and the second region 12 serving as electrode portions.

Moreover, since the cavity 6 is sealed by the membrane 7, the inside of the cavity 6 can be kept vacuum so that water does not exist in the cavity. Thus, attaching between the first region 11 and the second region 12 functioning as electrode portions can be prevented. Moreover, since alien substances such as water do not seep into the cavity 6, a dielectric constant in the cavity 6 is also kept constant. Accordingly, a pressure generated on the MEMS sensor 1 can be detected with a good precision.

Moreover, the electrostatic capacitive MEMS sensor 1 consumes a less amount of power in contribution to a limited on-time to the electrode portions. A pressure can be detected with a good precision by using the electrostatic capacitive MEMS sensor 1 with less power consumption.

Moreover, the n-type first region 11 including a diffusion layer is formed on the p-type semiconductor substrate 2. Because the first region 11 is separated from the semiconductor substrate 2, a potential of the first region 11 can be separately kept constant from the semiconductor substrate 2, and the first region 11 can be specified to have an appropriate concentration so as to function as an electrode portion.

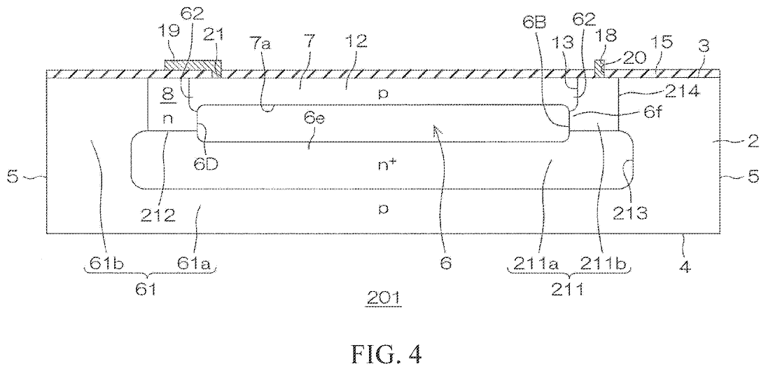

FIG. 4 shows a schematic section diagram of a MEMS sensor 201 according to a second embodiment of the present disclosure. In the second embodiment, only items different from those of the first embodiment are described, and constituting elements the same as those of the first embodiment are represented by the same denotations and associated details thereof omitted for brevity.

The MEMS sensor 201 includes a first region 211 in substitution for the first region 11 (referring to FIG. 2). The first region 211 includes a quadrilateral first portion 211a forming the bottom 6e of the cavity 6 in the plan view, and a loop-like second portion 211b forming the side 6f of the cavity 6. The second portion 11b is exposed through the first surface 3. The third region 61 is formed by a p-type region other than the first region 111 and the second region 12 in the semiconductor substrate 2. The first region 111 is selectively formed on a surface layer portion of the third region 61 to surround the cavity 6, and thus the second region 12 is selectively formed on a surface layer portion of the first region 111 in a region closer inside than the first region 111.

The first portion 211a and the second portion 211b are both formed by an n-type diffusion layer. A concentration of the n-type impurity of the first portion 211a is a first concentration. A concentration of the n-type impurity of the second portion 211b is a second concentration. The second concentration is less than the first concentration. The first concentration can be between about 1.0×10¹⁶ cm⁻³ and about 1.0×10²¹ cm⁻³. The second concentration can be between about 1.0×10¹⁵ cm⁻³ and about 1.0×10¹⁹ cm⁻³.

The first portion 211a is formed throughout an entirety of the bottom 6e of the cavity 6. The first portion 211a is further formed on a lower end of the side of of the cavity 6. An interface 212 between the first portion 211a and the second portion 211b is closer to the membrane 7 than a surface facing the opposite surface 7a of the membrane 7 in the bottom 6e of the cavity 6 and separated by the cavity 6 (that is, a bottom surface of the cavity 6). An outer periphery 213 of the first portion 211a is closer to an outside (a side of the four end surfaces 5) than an outer periphery 214 of the second portion 211b. In other words, the outer periphery 213 of the first portion 211a can be a pull-out portion further pulled outward toward a horizontal direction than the outer periphery 214 of the second portion 211b.

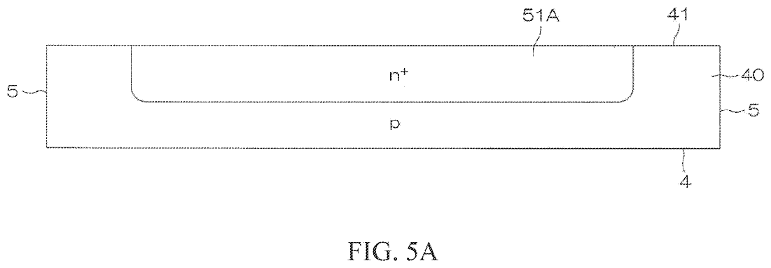

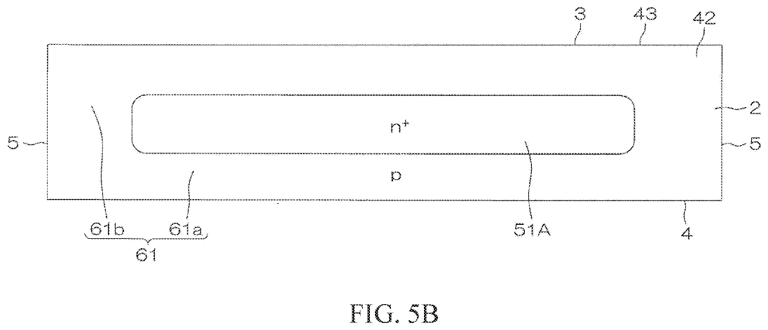

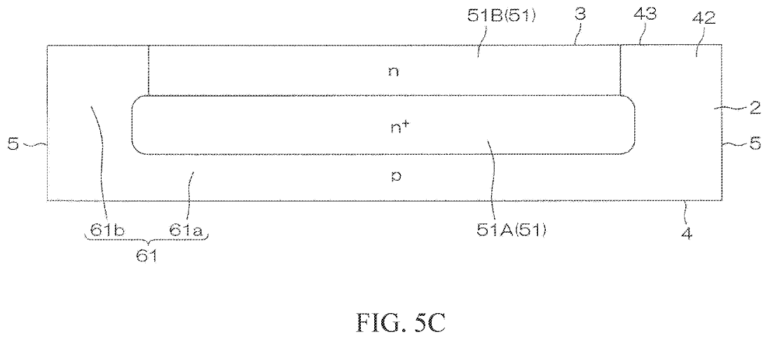

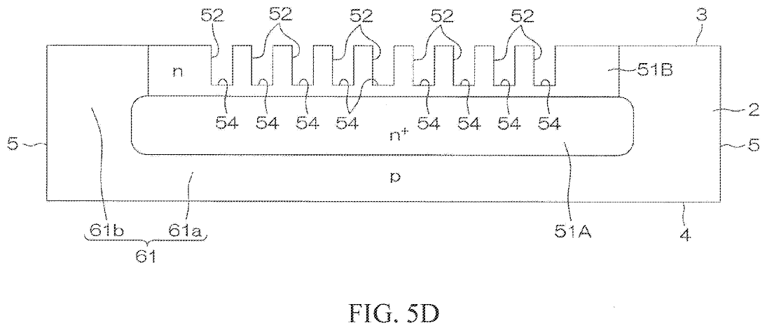

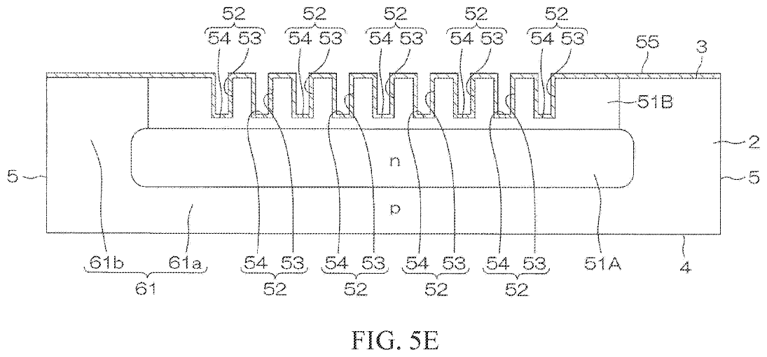

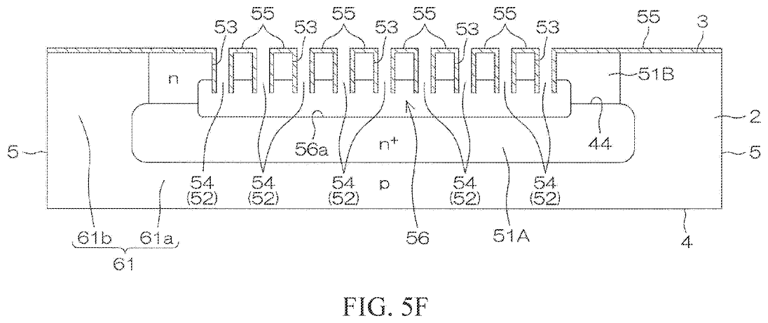

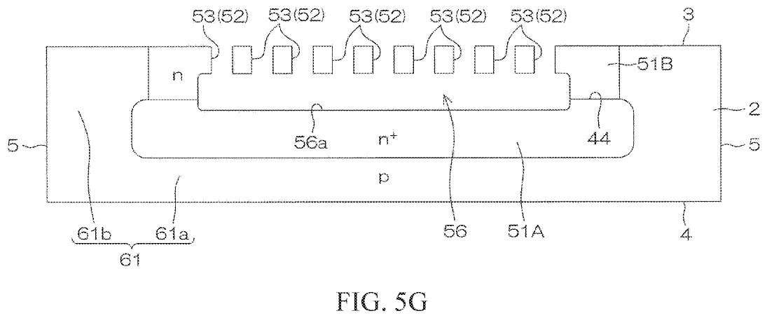

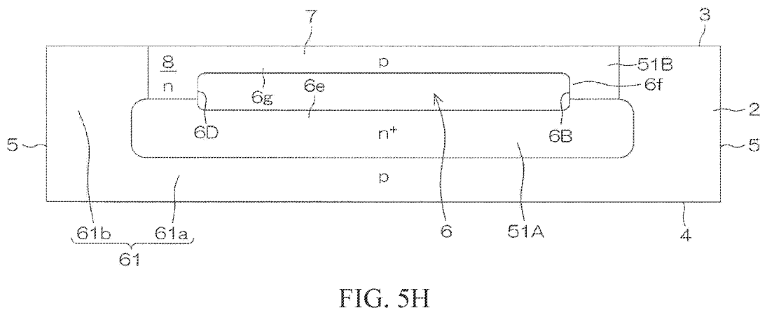

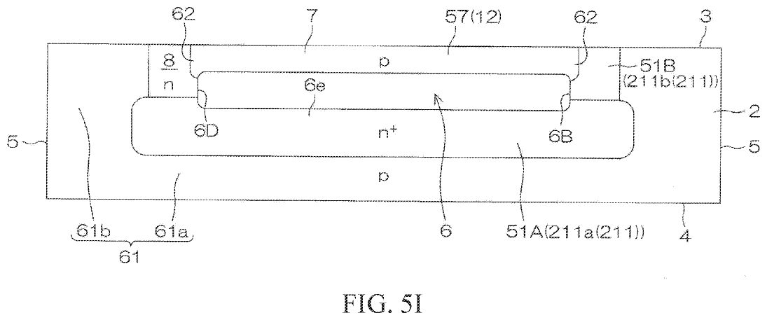

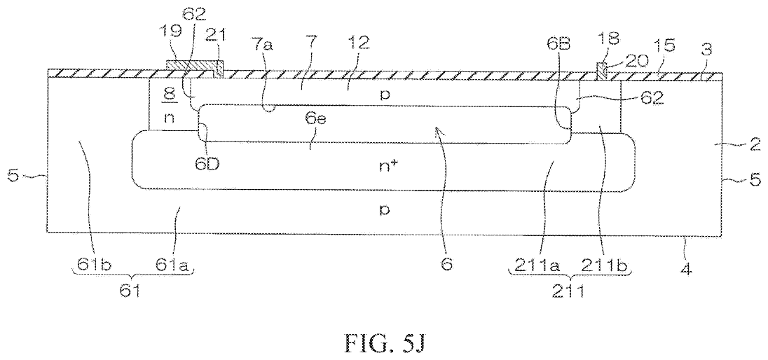

FIG. 5A to FIG. 5J show diagrams of a part of a manufacturing process of the MEMS sensor 201 according to the second embodiment of the present disclosure.

To manufacture the MEMS sensor 201, for example, as shown in FIG. 5A, a base substrate 40 including a silicon substrate is prepared. The base substrate 40 is p-type (second conductivity type) semiconductor wafer. The base substrate 40 has a front surface 41. An n-type (first conductivity type) impurity is selectively introduced into the front surface 41 of the base substrate 40. Accordingly, a first concentration diffusion layer 51A having a first concentration is formed on the front surface 41 of the base substrate 40. The first concentration can be between about 1.0×10¹⁶ cm⁻³ and about 1.0×10²¹ cm⁻³.

Next, as shown in FIG. 5B, a p-type epitaxial layer 42 is formed by epitaxially growing the p-type silicon on the front surface 41 formed with the first concentration diffusion layer 51A to cover the first concentration diffusion layer 51.

Next, as shown in FIG. 5C, an n-type impurity is selectively introduced into a front surface 43 of the epitaxial layer 42 to form a second concentration diffusion layer 51B having a second concentration. The second concentration is less than the first concentration. The second concentration can be between about 1.0×10¹⁵ cm⁻³ and about 1.0×10¹⁹ cm⁻³.

Accordingly, the n-type second concentration diffusion layer 51B is formed on the first surface 3 of the semiconductor substrate 2, and the first concentration diffusion layer 51A facing the second concentration diffusion layer 51B is formed on the second surface 4. The first concentration diffusion layer 51A and the second concentration diffusion layer 51B are included in the n-type first diffusion layer 51 (forming of a diffusion layer).

Next, multiple holes 52 recessed from the first surface 3 are formed in the second concentration diffusion layer 51B (forming of holes), as shown in FIG. 5D. Bottom walls 54 of the multiple holes 52 are located in the second concentration diffusion layer 51B. The multiple holes 52 are formed by means of, for example, deep dig etching (Bosch method). In the Bosch method, an area of a cross section perpendicular to a depth direction of the multiple holes 52 formed is constant.

Next, as shown in FIG. 5E, by means of CVD, a protective film 55 is formed on the first surface 3, sidewalls 53 of the multiple holes 52, and the bottom walls 54 of the multiple holes 52 (forming of a protective film). Accordingly, the first surface 3, the sidewalls 53 of the multiple holes 52 and the bottom walls 54 of the multiple holes 52 are covered by the protective film 35. The protective film 55 is, for example, silicon oxide.

Next, the protective film 55 is removed from the bottom walls 54 of the multiple holes 52 (removing of the protective film). Accordingly, a state of exposing the bottom walls 54 through the protective film 55 is formed on an inside of the multiple holes 52.

Next, as shown in FIG. 5F, the second concentration diffusion layer 51B and the first concentration diffusion layer 51A are isotropically etched. The etching is performed by an etching gas acting on the semiconductor material around the bottom walls 54 of the multiple holes 52 through the multiple holes 52 (etching). Accordingly, a connecting cavity 56 is formed below the multiple holes 52 (forming of a connecting cavity). A bottom 56a of the connecting cavity 56 is closer to the second surface 4 than an interface 44 between the first concentration diffusion layer 51A and the second concentration diffusion layer 51B.

Next, as shown in FIG. 5G, the protective film 55 is entirely removed by means of etching. That is to say, the protective film 55 is removed from the sidewalls 53 of the multiple holes 52 (removing of a second protective film). The etching can, for example, selectively remove silicon oxide.

Next, as shown in FIG. 5H, the multiple holes 52 are closed (closing of holes). More specifically, by means of thermal migration, the multiple holes 52 are closed by partially moving the semiconductor material, that is, Si, serving as the first concentration diffusion layer 51A around the multiple holes 52. Accordingly, a cavity 6 surrounded by the first diffusion layer 51 is formed, and thereby a membrane 7 sealing the cavity 6 is formed (forming of a cavity). The membrane 7 is merely a portion formed by Si, and is configured to be integrally formed with the fixing portion 8 which similarly includes Si without any connecting portion. Moreover, in the cavity 6 formed, the first concentration diffusion layer 51A is formed at the bottom 6e and the second concentration diffusion layer 51B is formed on the top 6g and the side 6f.

By implementing isotropic etching before thermal processing (thermal migration), the depth (a distance from the opposite surface 7a of the membrane 7 to the bottom 6e of the cavity 6) of the formed cavity 6 can become a desired depth and the thickness of the membrane 7 can become a desired thickness.

Next, as shown in FIG. 5I, a p-type impurity is selectively introduced into the membrane 7. Accordingly, a p-type second diffusion layer 57 is formed to be opposite to the first concentration diffusion layer 51A at the bottom 6e of the cavity 6 on the membrane 7 (forming of a second diffusion layer). The second diffusion layer 57 becomes the second region 12. The first concentration diffusion layer 51A becomes the first region 211a of the first region 211. A remaining region not introduced with the p-type impurity in the second concentration diffusion layer 51B becomes the second portion 211b of the first region 211.

Next, as shown in FIG. 5J, the insulation layer 15 is formed on the first surface 3 of the semiconductor substrate 2 by means of, for example, CVD. Next, the metal terminals 16 and 17 and the contacts 18 and 19 are formed on the insulation layer 15 by means of, for example, sputtering and patterning. Then, the MEMS sensor 201 can be obtained by cutting the semiconductor substrate 2 into individual chip sizes.

When a bias voltage is applied to the first contact 18 and the second contact 19, the first portion 211a functions as an electrode portion. Due to a higher concentration of the n-type impurity, a resistance of the first portion 211a can be reduced. Accordingly, compared to the MEMS sensor 1 of the first embodiment, power consumption can be reduced.

On the other hand, the second portion 211b having a lower concentration of the n-type impurity serves as a conduction path that electrically connects the first portion 211a with the first contact 18.

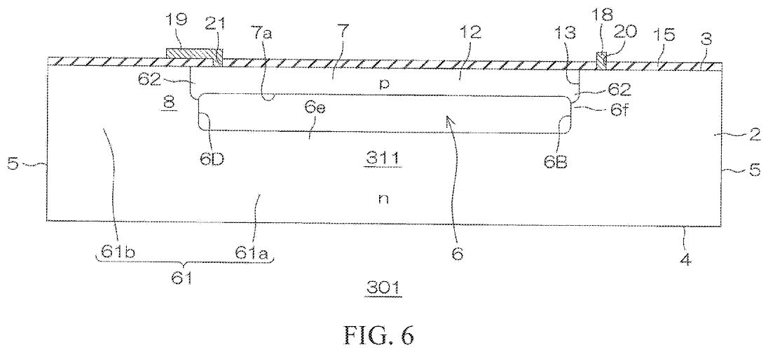

FIG. 6 shows a schematic plan view of a MEMS sensor 301 according to a third embodiment of the present disclosure. In the third embodiment, only items different from those of the first embodiment are described, and constituting elements the same as those of the first embodiment are represented by the same denotations and associated details thereof omitted for brevity.

In the MEMS sensor 301, the semiconductor substrate 2 is not a p-type (second conductivity type) semiconductor substrate, but is an n-type (first conductivity type) semiconductor substrate. In a region including the bottom 6e of the cavity 6, a first region 311 formed by an n-type semiconductor material of the semiconductor substrate 2 is used in substitution for the first region 11 including a diffusion layer.

Various embodiments of the present disclosure are as described above; however, the present disclosure may also be implemented in other configurations.

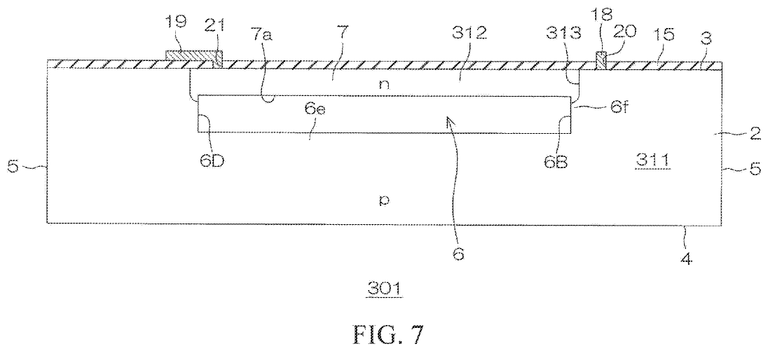

For example, a configuration in which the conductivity types of the individual semiconductor parts of the semiconductor device 301 are swapped can also be adopted. For example, in the MEMS sensors 1, 201 and 301, a p-type part may be n-type, and an n-type part may be p-type. A MEMS sensor 351 shown in FIG. 7 is a MEMS sensor formed by swapping the conductivity types of the MEMS sensor 301 of the third embodiment of the present disclosure.

The features given in the notes below can be extracted from the detailed description and the drawings of the present application.

### [Note 1-1]

A MEMS sensor (1, 201, 301, 351), comprising:

a semiconductor substrate (2) having a first surface (3) and a second surface (4) opposite to the first surface, and including a cavity (6);

a membrane (7) on the first surface (3) to seal the cavity (6);

a first region (11, 211 and 311) of a first conductivity type, formed at a bottom (6e) of the cavity (6); and

a second region (12) of a second conductivity type, formed on the membrane (7), facing the first region (11, 211 and 311) and separated from the first region (11, 211 and 311) by the cavity (6).

According to the configuration, the second region (12) of the second conductivity type formed on the membrane (7) faces the first region (11, 21 and 311) of the first conductivity type formed at the bottom (6e) of the cavity (6) and is separated from the first region (11, 211 and 311) by the cavity (6). When the membrane (7) receives a pressure from the first surface (3), the membrane (7) is deformed in a thickness direction of the semiconductor substrate (2) due to a pressure difference generated between an inside and an outside of the cavity (6). A distance between the first region (11, 211 and 311) and the second region (12) changes as the membrane (7) is deformed, and an electrostatic capacitance between the first region (11, 211 and 311) and the second region (12) also changes. Since the cavity (6) is sealed by the membrane (7), the inside of the cavity (6) is kept vacuum to prevent humidity such as moisture from seeping to the inside of the cavity (6). Thus, attaching between the first region (11, 211 and 311) and the second region (12) caused by such as moisture can be prevented. By using the first region (11, 211 and 311) and the second region (12) in different conductivity types as electrode portions, a change in the pressure can be well detected based on the change in the electrostatic capacitance between the electrode portions.

### [Note 1-2]

The MEMS sensor (1, 201) according to note 1-1, wherein the semiconductor substrate (2) is of the second conductivity type, and the first region (11, 211 and 311) includes a region formed at the bottom (6e) of the cavity (6) and a side (6f) of the cavity (6).

### [Note 1-3]

The MEMS sensor (1) according to note 1-2, wherein in the first region (11), a concentration of a portion (11a) forming the bottom of (6e) the cavity (6) is equal to a concentration of a portion (11b) forming the side (6f) of the cavity (6).

### [Note 1-4]

The MEMS sensor (2) according to note 1-2, wherein the first region (211) includes a first portion (211a) with a first concentration forming the bottom (6e) of the cavity (6), and a second portion (211b) with a lower concentration than the first concentration formed on the side (6f) of the cavity (6).

### [Note 1-5]

The MEMS sensor (1, 201) according to any one of note 1-2 to note 1-4, wherein a portion (11b, 211b) forming the side (6f) of the cavity (6) in the first region (11, 211) surrounds the second region (12).

### [Note 1-6]

The MEMS sensor (1, 201) according to any one of note 1—to note 1-5, wherein the second region (12) is exposed through the first surface (3), and the first region (11, 211) is exposed through the first surface (3).

### [Note 1-7]

The MEMS sensor (1, 201) according to note 1-6, further comprising:

a first contact (18) connected to the first region (11, 211) on the first surface (3); and

a second contact (19) connected to the second region (12) on the first surface (3).

### [Note 1-8]

The MEMS sensor (301, 351) according to note 1-1, wherein the semiconductor substrate (2) is of the first conductivity type.

### [Note 1-9]

A method of manufacturing a MEMS sensor (1, 201), comprising:

forming a first diffusion layer (31, 51) of a first conductivity type by introducing an impurity of the first conductivity type into a first surface (3) of a semiconductor substrate (2), wherein the semiconductor substrate (2) has the first surface (3) and a second surface (4) opposite to the first surface (3);

forming a cavity (6) disposed within and surrounded by the first diffusion layer (31, 51), and forming a membrane (7) sealing the cavity (6); and

forming a second diffusion layer (37, 57) of a second conductivity type opposite to the first diffusion layer (31, 51) at a bottom (6e) of the cavity (6) by introducing an impurity of the second conductivity type into the membrane (7).

### [Note 1-10]

The method of manufacturing the MEMS sensor (1, 201) according to note 1-9, wherein the forming of the cavity includes:

forming a plurality of holes (32, 52) recessed from the first surface (3) in the first diffusion layer (31, 51);

forming a connecting cavity (35, 56) below the plurality of holes (32, 52) by isotropically etching the first diffusion layer (31, 51) through the plurality of holes (32, 52); and

closing the plurality of holes (32, 52) and sealing the connecting cavity (36, 56) by partially moving a semiconductor material of the first diffusion layer (31, 51) around the plurality of holes (32, 52) to form the membrane (7), and thereby forming the cavity (6).

### [Note 1-11]

The method of manufacturing the MEMS sensor (1, 201) according to note 1-10, further comprising:

forming a protective film (35, 55) on sidewalls (33, 53) and bottom walls (34, 54) of the plurality of holes (32, 52);

removing the protective film (35, 55) from the bottom walls (34, 54) of the plurality of holes (32, 52); and

etching the plurality of holes (32, 52) to form the connecting cavity (36, 56).

### [Note 1-12]

The method of manufacturing the MEMS sensor (1, 201) according to note 1-11, after the etching, further comprising removing a second protective film to remove the protective film (35, 55) from the sidewalls (33, 53) of the plurality of holes (32, 52).

### [Note 1-13]

The method of manufacturing the MEMS sensor according to any one of note 1-9 to note 1-12, wherein the forming of the first diffusion layer includes:

selectively introducing impurities of a first conductivity type into a front surface of a base substrate (40) of a second conductivity type to form a first concentration diffusion layer (51A) having a first concentration;

forming an epitaxial layer (42) of the second conductivity type to cover the first concentration diffusion layer (51A); and

introducing impurities of the first conductivity type into a front surface (43) of the epitaxial layer (42) to form a second concentration diffusion layer (51B) having a second concentration lower than the first concentration, and wherein the forming of the cavity includes:

forming the first concentration diffusion layer (51A) at a bottom (6e); and

forming the cavity (6) having the second concentration diffusion layer (51B) at a top (6g) and a side (6f).

### [Note 1-14]

The method of manufacturing the MEMS sensor (201) according to note 1-13, wherein the forming of the cavity includes:

forming a plurality of holes (52) having bottom walls (54) in the second concentration diffusion layer (51B) by recessing the first surface (3) of the second concentration diffusion layer (51B);

forming a connecting cavity (56) below the plurality of holes (52) and having a bottom (56e) closer to the second surface (4) than an interface between the first concentration diffusion layer (51A) and the second concentration diffusion layer (51B) by isotropically etching the second concentration diffusion layer (51B) and the first concentration diffusion layer (51A) through the plurality of holes (52); and

closing the plurality of holes (52) and sealing the connecting cavity (56) by partially moving a semiconductor material of the first diffusion layer (51) around the plurality of holes (52) to form the membrane (7), and thereby forming the cavity (6).

### [Note 1-15]

The method of manufacturing the MEMS sensor (1) according to note 1-9, wherein the forming of the cavity includes:

forming a plurality of holes (52) recessed from the first surface (3) in the first diffusion layer (31); and

closing the plurality of holes (32) and thereby forming the cavity (6) by partially moving the semiconductor material of the first diffusion layer (31) around the plurality of holes (32).

1. A MEMS sensor, comprising:
a semiconductor substrate having a first surface and a second surface opposite to the first surface, and including a cavity;
a membrane on the first surface to seal the cavity;
a first region of a first conductivity type formed at a bottom of the cavity; and
a second region of a second conductivity type formed on the membrane, facing the first region and separated from the first region by the cavity.

2. The MEMS sensor of claim 1, wherein
the semiconductor substrate is of the second conductivity type, and
the first region includes a region formed at the bottom of the cavity and a side of the cavity.

3. The MEMS sensor of claim 2, wherein
in the first region, a concentration of a portion forming the bottom of the cavity is equal to a concentration of a portion forming the side of the cavity.

4. The MEMS sensor of claim 2, wherein the first region includes:
a first portion with a first concentration forming the bottom of the cavity; and
a second portion with a lower concentration than the first concentration formed on the side of the cavity.

5. The MEMS sensor of claim 2, wherein a portion forming the side of the cavity in the first region surrounds the second region.

6. The MEMS sensor of claim 3, wherein a portion forming the side of the cavity in the first region surrounds the second region.

7. The MEMS sensor of claim 4, wherein a portion forming the side of the cavity in the first region surrounds the second region.

8. The MEMS sensor of claim 2, wherein
the second region is exposed through the first surface, and
the first region is exposed through the first surface.

9. The MEMS sensor of claim 3, wherein
the second region is exposed through the first surface, and
the first region is exposed through the first surface.

10. The MEMS sensor of claim 4, wherein
the second region is exposed through the first surface, and
the first region is exposed through the first surface.

11. The MEMS sensor of claim 8, further comprising:
a first contact connected to the first region on the first surface; and
a second contact connected to the second region on the first surface.

12. The MEMS sensor of claim 1, wherein the semiconductor substrate is of the first conductivity type.

13. A method of manufacturing a MEMS sensor, comprising:
forming a first diffusion layer of a first conductivity type by introducing an impurity of the first conductivity type into a first surface of a semiconductor substrate, wherein the semiconductor substrate has the first surface and a second surface opposite to the first surface;
forming a cavity disposed within and surrounded by the first diffusion layer, and forming a membrane sealing the cavity; and
forming a second diffusion layer of a second conductivity type opposite to the first diffusion layer at a bottom of the cavity by introducing an impurity of the second conductivity type into the membrane.

14. The method of manufacturing the MEMS sensor according to claim 13, wherein the forming of the cavity includes:
forming a plurality of holes recessed from the first surface in the first diffusion layer; forming a connecting cavity below the plurality of holes by isotropically etching the first diffusion layer through the plurality of holes; and
closing the plurality of holes and sealing the connecting cavity by partially moving a semiconductor material of the first diffusion layer around the plurality of holes to form the membrane, and thereby forming the cavity.

15. The method of manufacturing the MEMS sensor according to claim 14, further comprising:
forming a protective film on sidewalls and bottom walls of the plurality of holes;
removing the protective film from the bottom walls of the plurality of holes; and
etching the plurality of holes to form the connecting cavity.

16. The method of manufacturing the MEMS sensor according to claim 15, after the etching, further comprising removing a second protective film to remove the protective film from the sidewalls of the plurality of holes.

17. The method of manufacturing the MEMS sensor according to claim 13, wherein the forming of the first diffusion layer includes:
selectively introducing impurities of a first conductivity type into a surface of a base substrate of a second conductivity type to form a first concentration diffusion layer having a first concentration;
forming an epitaxial layer of the second conductivity type to cover the first concentration diffusion layer; and
introducing impurities of the first conductivity type into a surface of the epitaxial layer to form a second concentration diffusion layer having a second concentration lower than the first concentration, and wherein the forming of the cavity includes:
forming the first concentration diffusion layer at a bottom; and
forming the cavity having the second concentration diffusion layer at a top and a side.

18. The method of manufacturing the MEMS sensor according to claim 14, wherein the forming of the first diffusion layer includes:
selectively introducing impurities of a first conductivity type into a surface of a base substrate of a second conductivity type to form a first concentration diffusion layer having a first concentration;
forming an epitaxial layer of the second conductivity type to cover the first concentration diffusion layer; and
introducing impurities of the first conductivity type into a surface of the epitaxial layer to form a second concentration diffusion layer having a second concentration lower than the first concentration, and wherein the forming of the cavity includes:
forming the first concentration diffusion layer at a bottom; and
forming the cavity having the second concentration diffusion layer at a top and a side.

19. The method of manufacturing the MEMS sensor according to claim 17, wherein the forming of the cavity includes:
forming a plurality of holes having bottom walls in the second concentration diffusion layer by recessing the first surface of the second concentration diffusion layer;
forming a connecting cavity below the plurality of holes and having a bottom closer to the second surface than an interface between the first concentration diffusion layer and the second concentration diffusion layer by isotropically etching the second concentration diffusion layer and the first concentration diffusion layer through the plurality of holes; and
forming the membrane and thereby forming the cavity by partially moving the semiconductor material of the first diffusion layer around the plurality of holes to close the plurality of holes and sealing the connecting cavity.

20. The method of manufacturing the MEMS sensor according to claim 13, wherein the forming of the cavity includes:
forming a plurality of holes recessed from the first surface in the first diffusion layer; and
closing the plurality of holes and thereby forming the cavity by partially moving the semiconductor material of the first diffusion layer around the plurality of holes.
